(19) United States
(12) Patent Application Publication
(10) Pub. No.: US 2022/0334797 A1
(43) Pub. Date: Oct. 20, 2022

(54) Nanomagnetic Multiplier using Dipole Nanomagnetic Structures

(71) Applicant: Redpine Signals, Inc., San Jose, CA (US)

(72) Inventors: Santhosh SIVASUBRAMANI, Madurai (IN); Sanghamitra DEBROY, Hyderabad (IN)

(73) Assignee: Redpine Signals, Inc., San Jose, CA (US)

(21) Appl. No.: 17/234,814

(22) Filed: Apr. 20, 2021

(51) Int. Cl. G06F 7/46; H01L 43/08; H01L 43/10

(52) U.S. Cl. CPC G06F 7/465; H01L 43/08; H01L 43/10; B82Y 25/00

(57) ABSTRACT

A multiplier is formed from a plurality of nanomagnetic structures including slant edge input nanomagnetic structures, diagonal elongate interconnect nanomagnetic structures, and output nanomagnetic structures. Input logic levels are provided by inserting a magnetic field, which generates an set of output magnetic fields representing the product of the binary input values.

### FIELD OF THE INVENTION

The present invention relates to a multiplier element. In particular, the invention relates to a nanomagnetic multiplier formed from regions of magnetic film on a substrate.

### BACKGROUND OF THE INVENTION

One class of memory and logic devices utilizes transistors such as P-channel and N-channel field effect transistors having a gate for controlling conductance between a drain and source terminal, which requires continuous application of power to maintain the logic state, with the input voltages applied to the device gates and outputs taken from the drain or source terminals in combination with other devices. A particularly complex logical operation is multiplication, which may require many such gates to form logical results, in one example by ORing minterms using logical AND gates, logical OR gates, and inverters to form a product on a bit by bit basis. Where the result of the multiplication needs to be stored, a separate memory structure known as flash memory may be used to take a result and store the result as a voltage which is stored as a charge in capacitors accessed using FET switches with low leakage, with the data persisting after removal of power. However, flash memory structures such as this have a limited number of storage cycles before they degrade and are unusable.

Another class of device for performing arithmetic and logical operations is known as Cellular Automata (CA), one such type of devices uses magnetic structures edge coupled to each other, the magnetic structures relying on the orientation of edge-coupled magnetic flux and proximity to adjacent neighboring cells to provide input excitation and output results. Although it is possible to form basic logic cells performing AND and OR functions, it has been difficult to provide a multiplier function. An advantage of using magnetic structures is that the information is stored in the magnetic or paramagnetic cell's magnetic state, and hence does not rely on charge storage as in transistor based structures. Accordingly, magnetic logic structures of the present invention have inherent memory that does not require the continued application of power.

It is desired to provide a multiplier using edge coupled magnetic structures which has memory for a previous computation result.

### OBJECTS OF THE INVENTION

A first object of the invention is a multiplier for binary input values and generating a binary multiplication result, the multiplier comprising:

a plurality of nanomagnetic structures arranged on a planar surface and indicating a binary value with a direction of magnetic field orientation;

at least one nanomagnetic structure comprising a slant edge input nanomagnetic structure coupled to an input value;

at least one nanomagnetic structure comprising an elongate interconnect nanomagnetic structure coupling a magnetic field from a nanomagnetic structure at one edge to a different nanomagnetic structure at an opposite edge of the elongate interconnect nanomagnetic structure;

a plurality of output structures generating a magnetic field representing a multiplication output value.

A second object of the invention is a nanomagnetic multiplier comprising a plurality nanomagnetic structures arranged in a sequence of a first column, second column, third column, fourth column, fifth column sixth column, seventh column, and eighth column;

the first column having, in sequence, a first C input nanomagnetic structure (NMS) and second C input NMS;

the second column having, in sequence, a b0 input NMS, a m0 output NMS, an a0 input NMS, an oval NMS, and a b1 input NMS, the m0 output NMS having an edge coupled to an edge of the first column first C input NMS, the oval NMS having an edge coupled to the first column second C input NMS;

the third column having, in sequence, an elongate diagonal NMS with a first end and a second end, the first end coupled to the second column a0 NMS and second column a0 oval NMS;

the fourth column having, in sequence, a B′ input NMS, an oval B NMS, and a b0 input NMS, the second end of the third column NMS coupled to the oval B NMS and b0 input NMS of the fourth column;

the fifth column having, in sequence, an A input NMS, an oval NMS, a Ci input NMS, an m1 output NMS, an A oval NMS, and a c′ input NMS, the oval NMS coupled to the fourth column B′ NMS, the m1 output NMS coupled to the fourth column oval B NMS;

the sixth column having, in sequence, a first diagonal interconnect NMS having a first end and a second end, an a1′ input NMS, an oval NMS, and a second diagonal interconnect NMS having a first end and a second end; the first diagonal interconnect first end positioned near the fifth column A input NMS and fifth column oval NMS, the second diagonal interconnect first end positioned near the sixth column oval NMS and b1′ input NMS;

the seventh column having, in sequence, a B′ oval NMS and a B input NMS;

the eighth column having, in sequence, an A input NMS, an m3 output NMS, a Ci input NMS, an m2 output NMS, and an A oval NMS coupled to the sixth column second diagonal interconnect second end, the eighth column m3 output NMS coupled to the seventh column B′ oval NMS, and the eighth column m2 output NMS coupled to the seventh column B input NMS,

where the digital inputs are applied as a magnetization to the a0 NMS, a1 NMS, b0 NMS, and b1 NMS, and the output is taken as a magnetization from the m0, m1, and m2 output NMS.

### SUMMARY OF THE INVENTION

A multiplier for generating a product from a first two bit binary input value and a second two bit binary input value comprises a planar arrangement of nanomagnetic structures including slant edge input nanomagnetic structures arranged on a vertical axis of a plane, diagonal interconnect nanomagnetic structures positioned approximately 45 degrees with respect to the vertical axis, and output nanomagnetic structures.

In one example of the invention, a nanomagnetic multiplier comprises a plurality nanomagnetic structures arranged in columns, including:

a first column having, in sequence, a first C input nanomagnetic structure (NMS) and second C input NMS;

a second column having, in sequence, a b0 input NMS, a m0 output NMS, an a0 input NMS, an oval NMS, and a b1 input NMS, the m0 output NMS having an edge coupled to an edge of the first column first C input NMS, the oval NMS having an edge coupled to the first column second C input NMS;

a third column having, in sequence, an elongate diagonal NMS with a first end and a second end, the first end coupled to the second column a0 NMS and second column a0 oval NMS;

a fourth column having, in sequence, a B′ input NMS, an oval B NMS, and a b0 input NMS, the second end of the third column NMS coupled to the oval B NMS and b0 input NMS of the fourth column;

a fifth column having, in sequence, an A input NMS, an oval NMS, a Ci input NMS, an m1 output NMS, an A oval NMS, and a c′ input NMS, the oval NMS coupled to the fourth column B′ NMS, the m1 output NMS coupled to the fourth column oval B NMS;

a sixth column having, in sequence, a first diagonal interconnect NMS having a first end and a second end, an a1′ input NMS, an oval NMS, and a second diagonal interconnect NMS having a first end and a second end; the first diagonal interconnect first end positioned near the fifth column A input NMS and fifth column oval NMS, the second diagonal interconnect first end positioned near the sixth column oval NMS and b1′ input NMS;

a seventh column having, in sequence, a B′ oval NMS and a B input NMS;

an eighth column having, in sequence, an A input NMS, an m3 output NMS, a Ci input NMS, an m2 output NMS, and an A oval NMS coupled to the sixth column second diagonal interconnect second end, the eighth column m3 output NMS coupled to the seventh column B′ oval NMS, and the eighth column m2 output NMS coupled to the seventh column B input NMS,

where the digital inputs are applied as a magnetization to the a0 NMS, a1 NMS, b0 NMS, and b1 NMS, and the output is taken as a magnetization from the m0, m1, and m2 output NMS.

### BRIEF DESCRIPTION OF THE DRAWINGS

FIG. 1 is a schematic diagram of a two bit multiplier generating a four bit output.

FIG. 2 is a truth table for a multiplier.

FIG. 3A is an example multiplication.

FIG. 3B is a plan view for magnetizations of FIG. 3A.

FIG. 4A is an example multiplication.

FIG. 4B is a plan view for magnetizations of FIG. 4A.

FIG. 5A is an example multiplication.

FIG. 5B is a plan view for magnetizations of FIG. 5A.

FIG. 6A is an example multiplication.

FIG. 6B is a plan view for magnetizations of FIG. 6A.

FIG. 7A is an example multiplication.

FIG. 7B is a plan view for magnetizations of FIG. 7A.

FIG. 8A is an example multiplication.

FIG. 8B is a plan view for magnetizations of FIG. 8A.

FIG. 9A is an example multiplication.

FIG. 9B is a plan view for magnetizations of FIG. 9A.

### DETAILED DESCRIPTION OF THE INVENTION

The present invention utilizes magnetic field coupled ferromagnetic single domain dots which rely on edge-coupled magnetic dipolar interactions to perform logical computations providing binary results. It is believed that computing with magnetic dots will provides great improvements in efficiency, as experiments have demonstrates that computational devices which rely on shape and positional anisotropy consume the least amount of energy allowed by the second law of thermodynamics, with the possibility of reaching the Landauer limit of k*T*ln(2) per bit, where k is the Boltzmann constant and T is the kelvin temperature in degrees K, and ln(2) is approximately 0.693. Magnetic Quantum-dot Cellular Automata (MQCA) devices began to be practical for computational use with material formulations that provide for room temperature operation.

Nanomagnetic computational devices have the additional advantage of retaining their magnetic states (non-volatile property) when powered off.

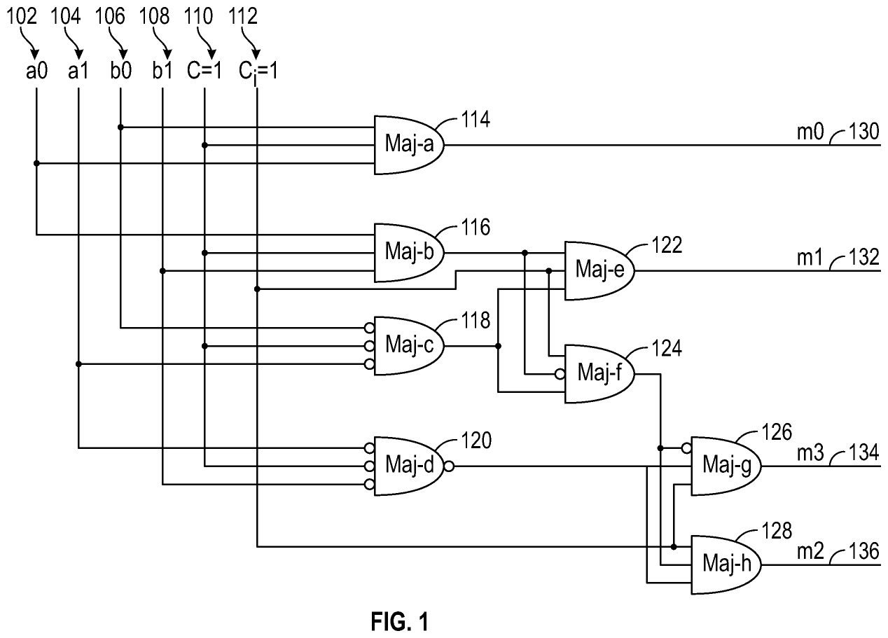

FIG. 1 shows a logic diagram for a multiplier according to the present invention, the multiplier forming the binary product [m3 m2 m1 m0] where:

[m3m2m1m0]=[a1a0]·[b1b0] (Equation 1)

and where each of the output bits of equation 1 may be computed as:

m3=a1·a0·b1·b0

m2=a1·a̅0̅·b1+a1·b1·b̅0̅

m1=a1·a̅0̅·b0+a1·b̅1̅·b0+a̅1̅·a0·b1+a0·b1·b̅0̅

m0=a0·b0

and where · indicates a logical AND function and + indicates a logical OR function, as is known in the art.

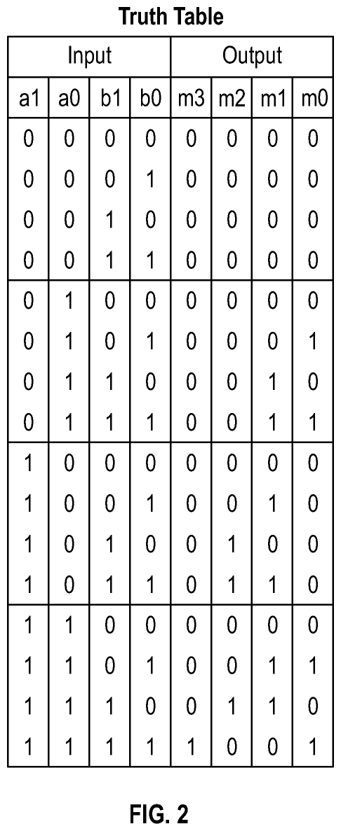

FIG. 2 shows a truth table for the multiplication of equation 1.

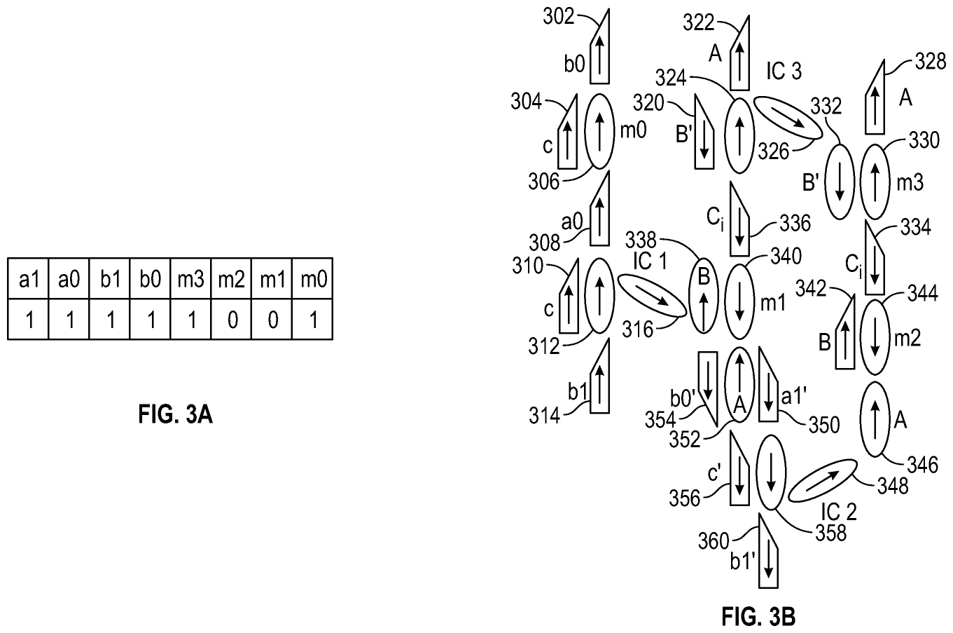

FIG. 3B shows a structure of the present invention with magnetizations indicated as arrows, the magnetizations reflecting the last entry of the truth table of FIG. 2 as indicated in associated FIG. 3A, comprising a plurality of nanomagnetic structures.

The nanomagnetic structures are selected for shape and positional anisotropy for generating the computations results, and use a mixture of shapes for reduction of the required area. Slant edged input nanomagnetic structures (providing shape anisotropy) and diagonal interconnect nanomagnetic structures of varying length (providing positional anisotropy) reduce the number of nanomagnetic structures in the design, and reduces signal propagation time while providing reduced attenuation.

Magnetic anisotropic energy which provides the coupling and storage in the present invention originates with the interaction referred as spin orbit coupling.

The nanomagnetic structures may be preferably formed from Permalloy (Py) comprising 78.5% nickel, and 21.5% iron which is a pronounced soft ferromagnetic material with low coercive field by nature. As its exchange energy is larger than the magnetocrystalline anisotropy and low magnetic anisotropy energy (MAE), the exchange interaction dominates the magnetic anisotropy. In one example of the invention, the value of maximum torque is on the order of 10⁻⁵ A/m. Permalloy possess zero uniaxial anisotropy constant which is advantageous where the magnetic field storage depends on the shape of the dot and it tends to align to its primary axis. The exchange Hamiltonian on a single domain nano-magnetic structure requires high axial symmetry to maintain its magnetic anisotropy. In one example of the invention, the exchange stiffness constant is 13×10⁻¹² J/m, with a damping coefficient of 0.25 and saturation magnetization of 800×103 A/m.

Device inputs are formed as slant edge input nanomagnetic structures for inputs a0 308, a1 350, b0 302 354, and b1 314. Slant edge complement nanomagnetic structures are inverted versions of input signals and indicated with an apostrophe (′), including b0′ 354, b1′ 314, and slant edge nanomagnetic structures with static inputs set to 1 such as c 304 and 310 and complement c′ 356. Input values may be conveyed to the input nanomagnetic structures using brief current pulses in a wire which couple magnetic field into the input nanomagnetic structures.

Diagonal nanomagnetic structures are used for coupling a magnetic field with an intermediate computational result from one region to another depicted as elongate ovals with an interconnect (IC) notation, and include IC1 316, IC2 348, and IC3 326. The diagonal interconnects are oriented approximately 45 degrees with respect to the other vertical structures such as 302 and 322. The diagonal interconnects provide tolerance against misalignment of the magnetic field being coupled and the slanted edges of the input nanomagnetic structures improve reliability when the dots are of modest size and require a smaller magnetic field applied for initialization of the multiplier.

The output structures of FIG. 3B are m0 306, m1 340, m2 344, and m3 330.

In one example of the invention, the oval nanomagnetic structures have planar dimensions on the order of 10 nm×30 nm with a thickness of 10 nm and an edge separation to other structures of 10-15 nm. The slant edge nanomagnetic structures have planar dimensions on the order of 15 nm×30 nm with a thickness of 10 nm. The diagonal elongate nanomagnetic structures have a width on the order of 10 nm and variable length as required, typically 50-70 nm with a thickness of 10 nm and positioned at an angle of approximately 45 degrees.

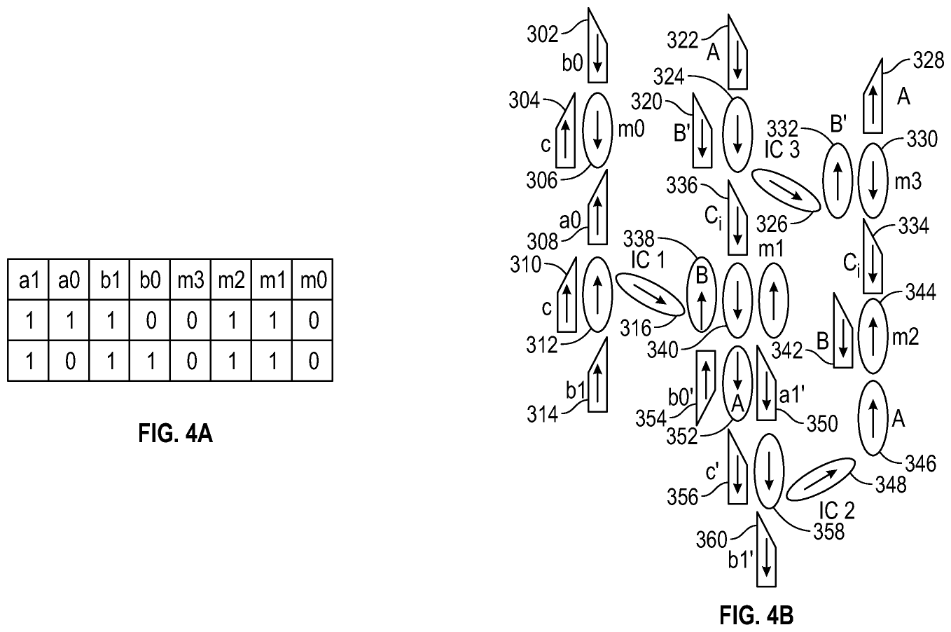

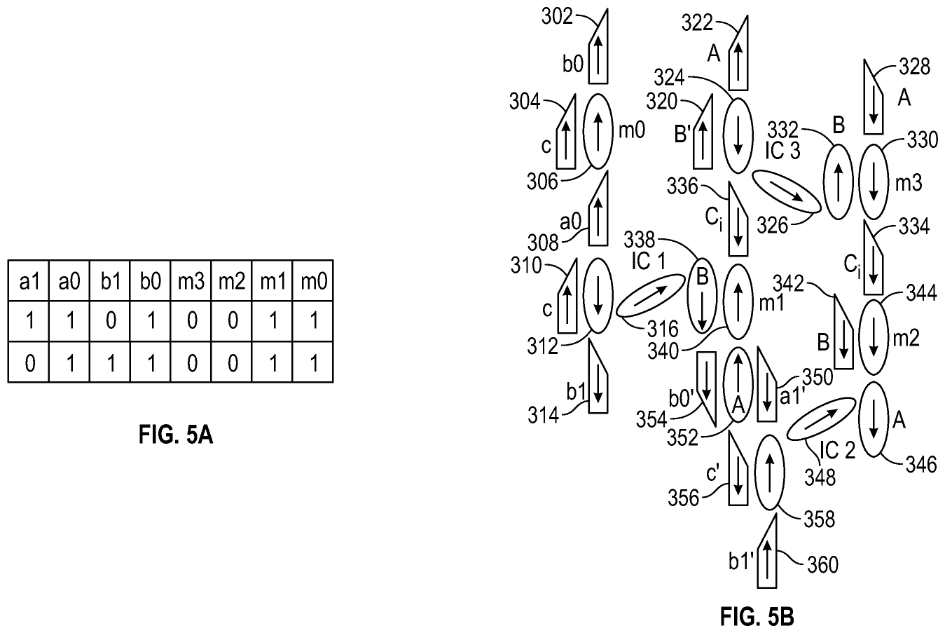

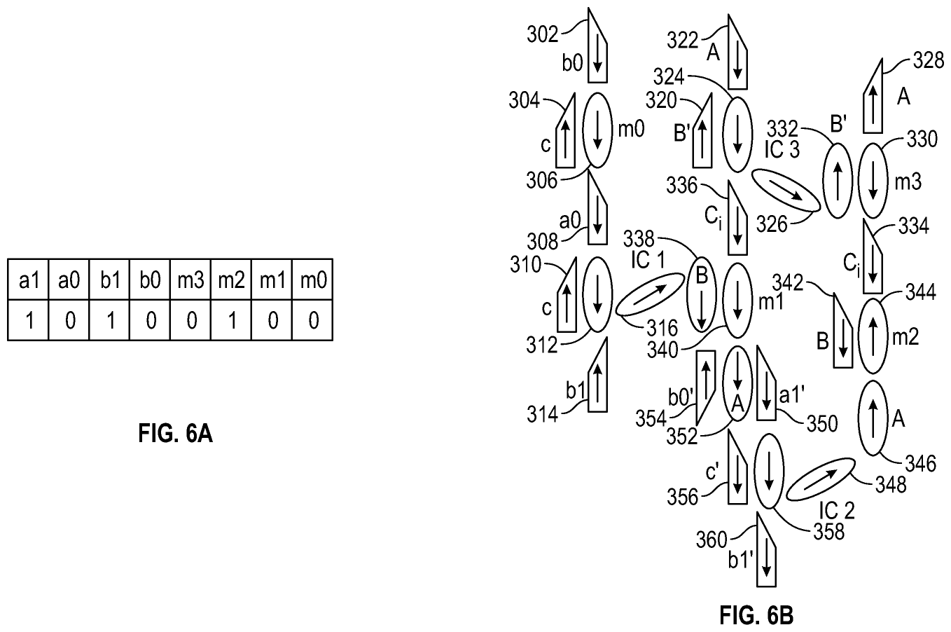

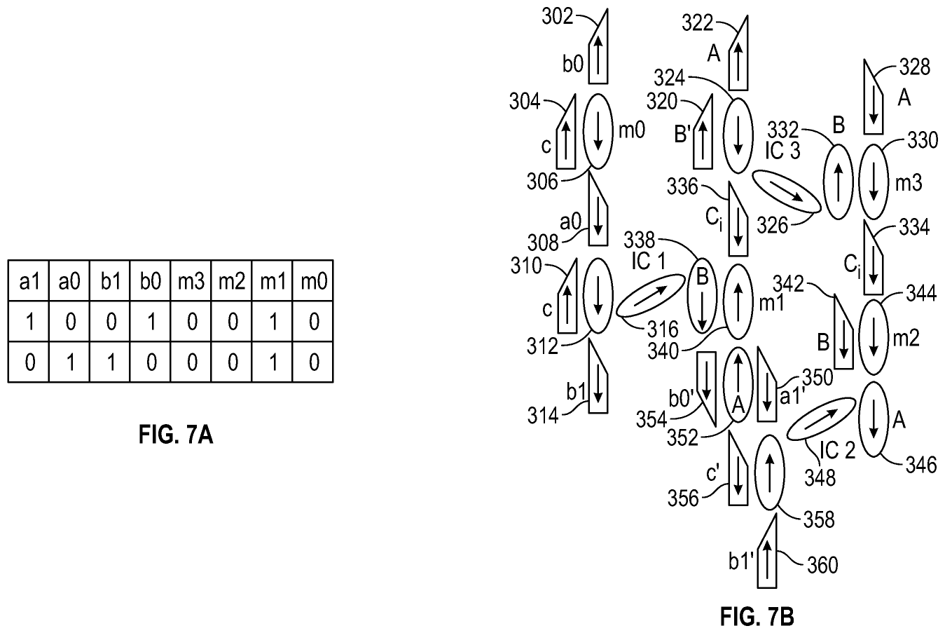

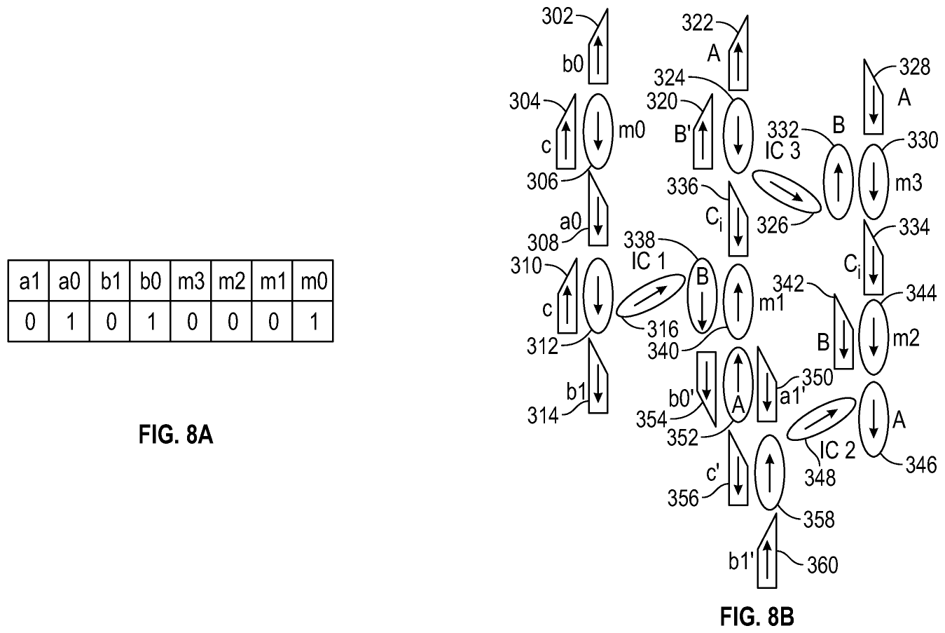

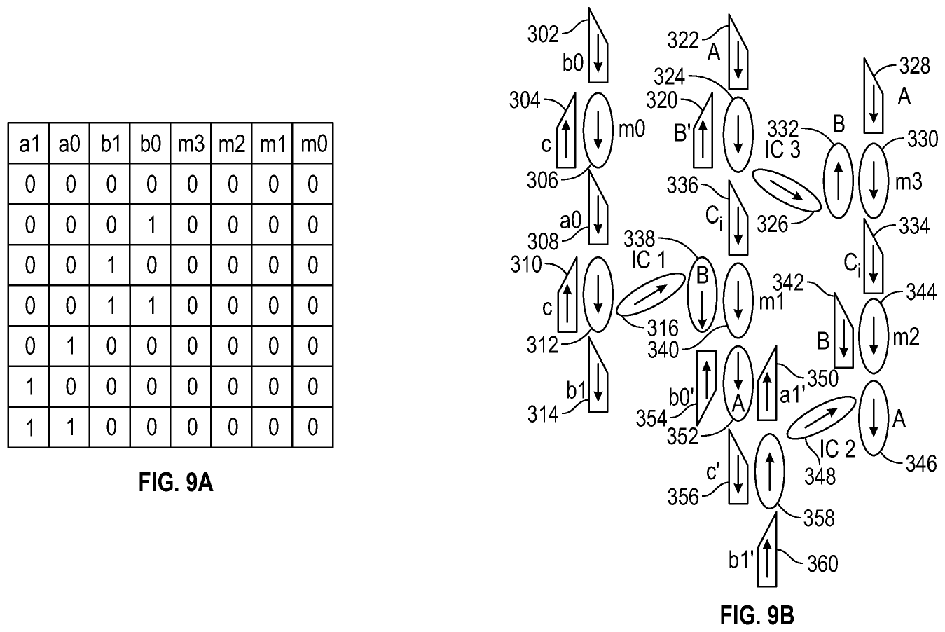

The input magnetizations for other truth table entries are shown in FIGS. 4A through 9A, and magnetization diagrams for the structures in associated FIGS. 4B through 9B. For simplicity, certain of the figures show multiple input values [a1 a0] and [b1 b0] producing a single magnetization output [m2 m1 m0]. For the cases where multiple inputs generate a particular output, only the inputs for the first entry of the corresponding A suffix figure truth table are indicated in the associated B suffix figure. For example, FIG. 4B shows the magnetizations for input [a1 a0]=[1 1] and [b1 b0]=[1 0] of FIG. 4A, FIG. 5B shows the magnetizations for input [a1 a0]=[1 1] and [b1 b0]=[0 1] of FIG. 5A, FIG. 7B shows the magnetizations for input [a1 a0]=[1 0] and [b1 b0]=[0 1] of FIG. 7A, and FIG. 9B shows the magnetizations for input [a1 a0]=[0 0] and [b1 b0]=[0 0] of FIG. 9A.

In one example of the invention, the logic input flux density coupled to an input nanomagnetic structure is +0.5 Tesla for a 1 and −0.5 T for a 0.

In the present application, a value which is approximately a nominal value is understood to be +/−50% of the nominal value for a nominal linear dimension, or +/−20 degrees for a nominal angular value. Accordingly, approximately 45 degrees is understood to be any value in the range of 25 degrees to 65 degrees. A value which is “on the order of” a nominal value is understood to be in the range of 1/10th of the nominal value to 10x the nominal value.

The present examples are provided for illustrative purposes only, and are not intended to limit the invention to only the embodiments shown.

We claim:

1) A multiplier for binary input values and generating a binary multiplication result, the multiplier comprising:
a plurality of nanomagnetic structures arranged on a planar surface and indicating a binary value with a direction of magnetic field orientation:
at least one nanomagnetic structure comprising a slant edge input nanomagnetic structure coupled to an input value;
at least one nanomagnetic structure comprising an elongate interconnect nanomagnetic structure coupling a magnetic field from a nanomagnetic structure at one edge to a different nanomagnetic structure at an opposite edge of the elongate interconnect nanomagnetic structure;
a plurality of output structures generating a magnetic field representing a multiplication output value.

2) The multiplier of claim 1 where a one value coupled to an input is on the order of 0.5 T and a zero value coupled to an input is on the order of −0.5 T.

3) The multiplier of claim 1 where the diagonal interconnect is approximately 45 degrees with respect to a vertical axis.

4) The multiplier of claim 1 where at least one of the nanomagnetic structures comprises Permalloy (Py).

5) A nanomagnetic multiplier comprising a plurality nanomagnetic structures arranged in a sequence of a first column, second column, third column, fourth column, fifth column sixth column, seventh column, and eighth column;
the first column having, in sequence, a first C input nanomagnetic structure (NMS) and second C input NMS;
the second column having, in sequence, a b0 input NMS, a m0 output NMS, an a0 input NMS, an oval NMS, and a b1 input NMS, the m0 output NMS having an edge coupled to an edge of the first column first C input NMS, the oval NMS having an edge coupled to the first column second C input NMS;
the third column having, in sequence, an elongate diagonal NMS with a first end and a second end, the first end coupled to the second column a0 NMS and second column a0 oval NMS;
the fourth column having, in sequence, a B′ input NMS, an oval B NMS, and a b0 input NMS, the second end of the third column NMS coupled to the oval B NMS and b0 input NMS of the fourth column;
the fifth column having, in sequence, an A input NMS, an oval NMS, a Ci input NMS, an m1 output NMS, an A oval NMS, and a c′ input NMS, the oval NMS coupled to the fourth column B′ NMS, the m1 output NMS coupled to the fourth column oval B NMS;
the sixth column having, in sequence, a first diagonal interconnect NMS having a first end and a second end, an a1′ input NMS, an oval NMS, and a second diagonal interconnect NMS having a first end and a second end; the first diagonal interconnect first end positioned near the fifth column A input NMS and fifth column oval NMS, the second diagonal interconnect first end positioned near the sixth column oval NMS and b1′ input NMS;
the seventh column having, in sequence, a B′ oval NMS and a B input NMS;
the eighth column having, in sequence, an A input NMS, an m3 output NMS, a Ci input NMS, an m2 output NMS, and an A oval NMS coupled to the sixth column second diagonal interconnect second end, the eighth column m3 output NMS coupled to the seventh column B′ oval NMS, and the eighth column m2 output NMS coupled to the seventh column B input NMS,
where the digital inputs are applied as a magnetization to the a0 NMS, a1 NMS, b0 NMS, and b1 NMS, and the output is taken as a magnetization from the m0, m1, and m2 output NMS.

6) The multiplier of claim 5 where a one value coupled to an input is on the order of 0.5 T and a zero value coupled to an input is on the order of −0.5 T.

7) The multiplier of claim 5 where the diagonal interconnect is approximately 45 degrees with respect to a vertical axis.

8) The multiplier of claim 5 where at least one of the nanomagnetic structures comprises Permalloy (Py).
